(19) United States
(12) Patent Application Publication
(10) Pub. No.: US 2021/0082790 A1
(43) Pub. Date: Mar. 18, 2021

(54) POWER SEMICONDUCTOR PACKAGE HAVING INTEGRATED INDUCTOR AND METHOD OF MAKING THE SAME

(71) Applicant: Alpha and Omega Semiconductor (Cayman), Ltd., Grand Cayman (KY)

(72) Inventors: Xiaotian Zhang, San Jose, CA (US); Mary Jane R. Alin, Shanghai (CN); Bo Chen, Shanghai (CN); David Brian Oraboni, JR., San Jose, CA (US); Long-Ching Wang, Cupertino, CA (US)

(73) Assignee: Alpha and Omega Semiconductor (Cayman) Ltd., Grand Cayman (KY)

(21) Appl. No.: 16/575,193

(22) Filed: Sep. 18, 2019

(51) Int. Cl. H01L 23/495; H01L 21/56; H01L 21/48; H01L 23/31; H01L 23/522; H01L 49/02

(52) U.S. Cl. CPC H01L 23/49524; H01L 21/565; H01L 21/4825; H01L 28/10; H01L 23/49575; H01L 23/3157; H01L 23/5227; H01L 23/49503

(57) ABSTRACT

A power semiconductor package includes a lead frame, a low side field-effect transistor (FET), a high side FET, a first metal clip, a second metal clip, an inductor assembly, and a molding encapsulation. The low side FET is flipped and is attached to a first die paddle of the lead frame. A method for fabricating a power semiconductor package. The method comprises the steps of providing a lead frame; attaching a low side FET and a high side FET to the lead frame; mounting a first metal clip and a second metal clip; mounting an inductor; forming a molding encapsulation; and applying a singulation process.

### FIELD OF THE INVENTION

This invention relates generally to a power semiconductor package and a method of making the same. More particularly, the present invention relates to a driver metal-oxide-silicon transistor (DrMOS) having an integrated inductor.

### BACKGROUND OF THE INVENTION

A conventional DrMOS has an inductor outside of the DrMOS package. FIG. 2 of U.S. Pat. No. 10,111,333 to Yin et al. has an inductor in a switching-power-supply module. The present disclosure has an integrated inductor in the DrMOS package. The present disclosure further uses metal clip interconnections to reduce electrical noise and to increase thermal dissipation.

The power semiconductor package of the present disclosure comprises a controller, two field-effect transistors (FETs), and an inductor. The advantages include a smaller form factor, better thermal dissipation, and higher electrical efficiency because of the integrated inductor. With an integrated approach, a complete switching power stage is optimized with regard to driver and FET dynamic performance, system inductance, and power FET R_{DS(ON)}.

### SUMMARY OF THE INVENTION

The present invention discloses a power semiconductor package comprising a lead frame, a low side field-effect transistor (FET), a high side FET, a first metal clip, a second metal clip, an inductor assembly, and a molding encapsulation. The low side FET is flipped and is attached to a first die paddle of the lead frame.

A method for fabricating a power semiconductor package is also disclosed. The method comprises the steps of providing a lead frame; attaching a low side FET and a high side FET to the lead frame; mounting a first metal clip and a second metal clip; mounting an inductor; forming a molding encapsulation; and applying a singulation process.

### BRIEF DESCRIPTION OF THE DRAWINGS

FIG. 1 is a perspective view of a power semiconductor package in examples of the present disclosure.

FIG. 2 is a cross sectional plot of the power semiconductor package of FIG. 1 in examples of the present disclosure.

FIG. 3 is a circuit diagram of a DrMOS in examples of the present disclosure.

FIG. 4 is a flowchart of a process to develop a power semiconductor package in examples of the present disclosure.

FIGS. 5A, 5B, 5C, 5D, 5E, and 5F show the steps of the process to fabricate the power semiconductor package in examples of the present disclosure.

### DETAILED DESCRIPTION OF THE INVENTION

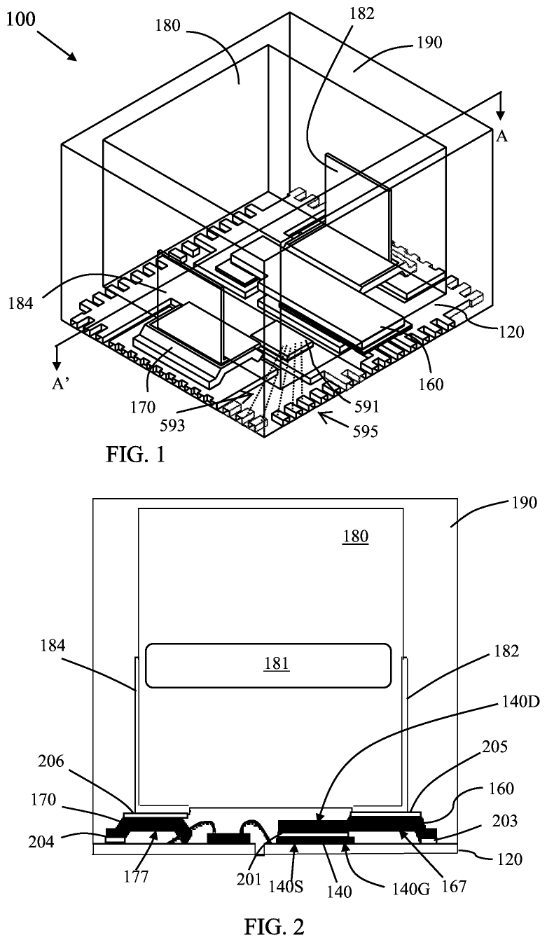

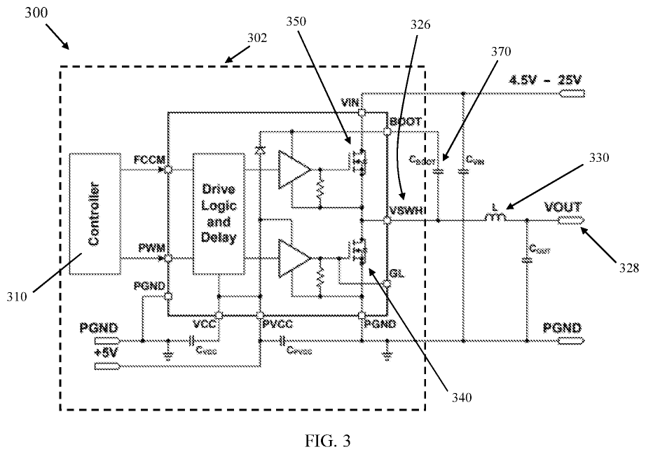

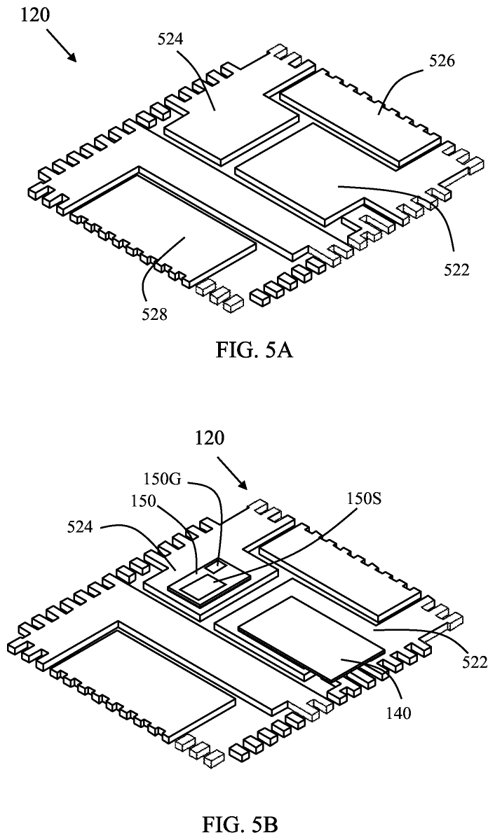

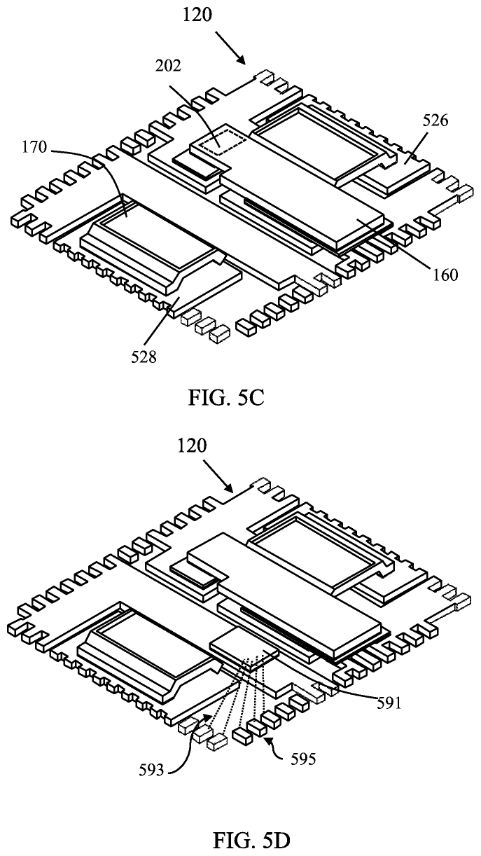

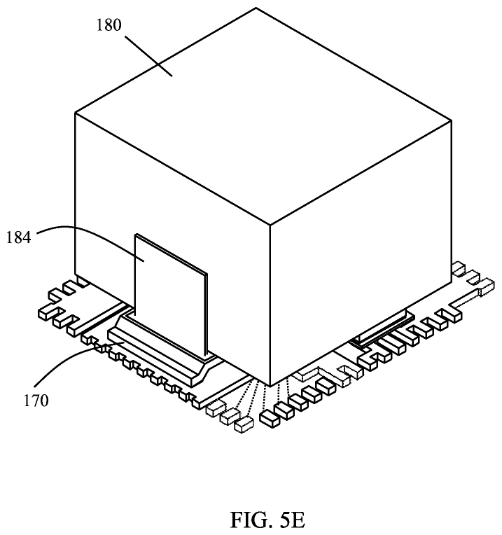

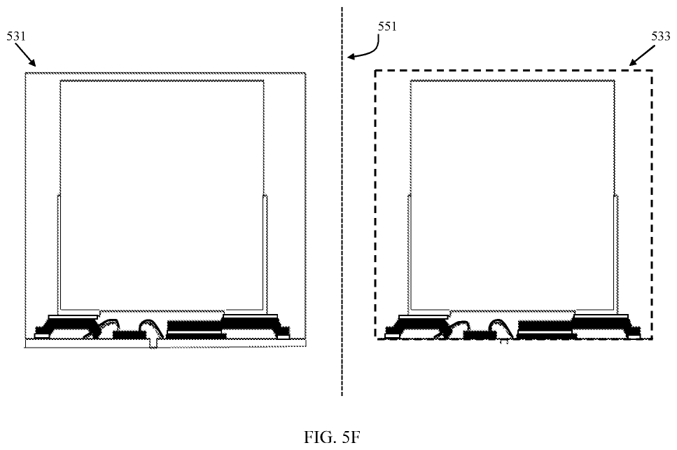

FIG. 1 is a perspective view of a power semiconductor package 100 in examples of the present disclosure. FIG. 2 is a cross sectional plot of the power semiconductor package 100 along AA′ of FIG. 1. The power semiconductor package 100 comprises a lead frame 120, a low side field-effect transistor (FET) 140, a high side FET 150 of FIG. 5B, a first metal clip 160, a second metal clip 170, an inductor assembly 180, and a molding encapsulation 190. The lead frame 120 comprises a first die paddle 522 of FIG. 5A, a second die paddle 524, a first end paddle 526, and a second end paddle 528. The first end paddle 526 is electrically connected to a switching node VSWH terminal 326 of FIG. 3. The second end paddle 528 is electrically connected to a Vout terminal 328 of FIG. 3.

The low side FET 140 is flipped and is attached to the first die paddle 522. The low side FET 140 comprises a source electrode 140S and a gate electrode 140G on a top surface of the low side FET 140. The high side FET 150 is attached to the second die paddle 524. The high side FET 150 comprises a source electrode 150S of FIG. 5B and a gate electrode 150G on a top surface of the high side FET 150.

The first metal clip 160 connects a drain electrode 140D of the low side FET 140 and the source electrode 1505 of FIG. 5B of the high side FET 150 to the first end paddle 526 of FIG. 5A of the lead frame 120. The second metal clip 170 is mounted on the second end paddle 528 of FIG. 5A of the lead frame 120.

The inductor assembly 180 comprises a coil 181; a first lead 182 connecting to the first metal clip 160; and a second lead 184 connecting to the second metal clip 170.

The molding encapsulation 190 encloses the low side FET 140, the high side FET 150, the first metal clip 160, the second metal clip 170, the inductor assembly 180, and a majority portion of the lead frame 120. In examples of the present disclosure, a bottom surface of the lead frame 120 is exposed from the molding encapsulation 190.

In examples of the present disclosure, the first metal clip 160 is electrically and mechanically connected to the drain electrode 140D of the low side FET 140 by a first conductive material 201. The first metal clip 160 is electrically and mechanically connected to the source electrode 150S of the high side FET 150 by a second conductive material 202 of FIG. 5C (shown in dashed lines). The first metal clip 160 is electrically and mechanically connected to the first end paddle 526 of the lead frame 120 by a third conductive material 203. The second metal clip 170 is electrically and mechanically connected to the second end paddle 528 of the lead frame 120 by a fourth conductive material 204. In examples of the present disclosure, the first conductive material 201 is made of a solder paste material. The second conductive material 202 is made of a solder paste material. The third conductive material 203 is made of a solder paste material. The fourth conductive material 204 is made of a solder paste material.

In examples of the present disclosure, the first metal clip 160 comprises an elevated section 167. The first lead 182 of the inductor assembly 180 is electrically and mechanically connected to the elevated section 167 of the first metal clip 160 by a fifth conductive material 205. The second metal clip 170 comprises an elevated section 177. The second lead 184 of the inductor assembly 180 is electrically and mechanically connected to the elevated section 177 of the second metal clip 170 by a sixth conductive material 206.

In examples of the present disclosure, each of the fifth conductive material 205 and the sixth conductive material 206 comprises a power metallurgy material implemented by a hybrid sintering process.

In examples of the present disclosure, each of the fifth conductive material 205 and the sixth conductive material 206 comprises an elastomer material.

In examples of the present disclosure, each of the fifth conductive material 205 and the sixth conductive material 206 comprises an epoxy material.

In examples of the present disclosure, an integrated circuit (IC) 591 is mounted on the lead frame 120. A plurality of bonding wires 593 connect the IC 591 to a plurality of leads 595 of the lead frame 120.

FIG. 3 is a circuit diagram 300 of a DrMOS in examples of the present disclosure. The DrMOS comprises a sub-package 302, an inductor 330, and a plurality of capacitors 370. The sub-package 302 comprises a controller 310, a low side FET 340, and a high side FET 350.

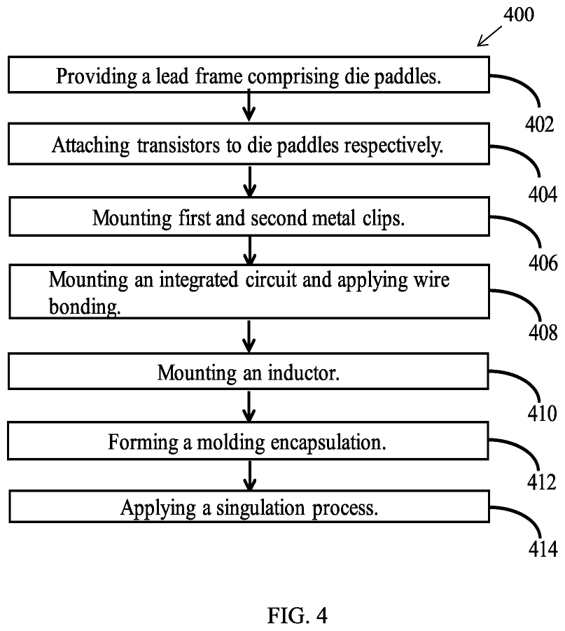

FIG. 4 is a flowchart of a process 400 to develop a power semiconductor package in examples of the present disclosure. The process 400 may start from block 402. For simplicity, the right one in dashed lines of FIG. 5F (same structure as the corresponding left one in solid lines) is not shown in FIGS. 5A, 5B, 5C, 5D, and 5E.

In block 402, referring now to FIG. 5A, a lead frame 120 is provided. The lead frame 120 comprises a first die paddle 522, a second die paddle 524, a first end paddle 526, and a second end paddle 528. Block 402 may be followed by block 404.

In block 404, referring now to FIG. 5A, a low side FET 140 is flipped and is attached to the first die paddle 522. The low side FET 140 comprises a source electrode 140S of FIG. 2 and a gate electrode 140G of FIG. 2 on a top surface of the low side FET 140. The high side FET 150 is attached to the second die paddle 524. The high side FET 150 comprises a source electrode 1505 and a gate electrode 150G on a top surface of the high side FET 150. Block 404 may be followed by block 406.

In block 406, referring now to FIG. 5C, the first metal clip 160 connects a drain electrode 140D of FIG. 2 of the low side FET 140 and the source electrode 1505 of FIG. 5B of the high side FET 150 to the first end paddle 526 of the lead frame 120. The second metal clip 170 is mounted on the second end paddle 528 of the lead frame 120.

The first metal clip 160 is electrically and mechanically connected to the drain electrode 140D of FIG. 2 of the low side FET 140 by a first conductive material 201 of FIG. 2. The first metal clip 160 is electrically and mechanically connected to the source electrode 150S of FIG. 5B of the high side FET 150 by a second conductive material 202 (shown in dashed lines). The first metal clip 160 is electrically and mechanically connected to the first end paddle 526 of the lead frame 120 by a third conductive material 203 of FIG. 2. The second metal clip 170 is electrically and mechanically connected to the second end paddle 528 of the lead frame 120 by a fourth conductive material 204 of FIG. 2. In examples of the present disclosure, the first conductive material 201 is made of a solder paste material. The second conductive material 202 is made of a solder paste material. The third conductive material 203 is made of a solder paste material. The fourth conductive material 204 is made of a solder paste material. In examples of the present disclosure, the solder paste material contains lead (Pb). A reflow temperature for the solder paste material is higher than two hundred degrees Centigrade. Block 406 may be followed by block 408.

In block 408, referring now to FIGS. 5D, an integrated circuit (IC) 591 is mounted on the lead frame 120. A plurality of bonding wires 593 connect the IC 591 to a plurality of leads 595 of the lead frame 120. Block 408 may be followed by block 410.

In block 410, referring now to FIG. 5E, an inductor assembly 180 is mounted on the first metal clip 160 of FIG. 5C and the second metal clip 170. The inductor assembly 180 comprises a coil 181 of FIG. 2; a first lead 182 connecting to the first metal clip 160 of FIG. 5C; and a second lead 184 connecting to the second metal clip 170.

The first metal clip 160 comprises an elevated section 167 of FIG. 2. The first lead 182 of the inductor assembly 180 is electrically and mechanically connected to the elevated section 167 of FIG. 2 of the first metal clip 160 by a fifth conductive material 205 (a first selected conductive material) of FIG. 2. The second metal clip 170 comprises an elevated section 177 of FIG. 2. The second lead 184 of the inductor assembly 180 is electrically and mechanically connected to the elevated section 177 of FIG. 2 of the second metal clip 170 by a sixth conductive material 206 (a second selected conductive material) of FIG. 2.

In examples of the present disclosure, each of the fifth conductive material 205 (a first selected conductive material) and the sixth conductive material 206 (a second selected conductive material) comprises a power metallurgy material implemented by a hybrid sintering process at a temperature in a range from 195 degrees Centigrade to 205 degrees Centigrade.

In examples of the present disclosure, each of the fifth conductive material 205 and the sixth conductive material 206 comprises an elastomer material processed at a temperature in a range from 75 degrees Centigrade to 85 degrees Centigrade.

In examples of the present disclosure, each of the fifth conductive material 205 and the sixth conductive material 206 comprises an epoxy material processed at a temperature in a range from 170 degrees Centigrade to 180 degrees Centigrade. Block 410 may be followed by block 412.

In block 412, referring now to FIG. 1, a molding encapsulation 190 is formed. The molding encapsulation 190 encloses the low side FET 140, the high side FET 150, the first metal clip 160, the second metal clip 170, the inductor assembly 180, and a majority portion of the lead frame 120. In examples of the present disclosure, a bottom surface of the lead frame 120 is exposed from the molding encapsulation 190. Block 412 may be followed by block 414.

In block 414, referring now to FIG. 5F, a singulation process along the line 551 is applied. The power semiconductor package 531 is separated from an adjacent power semiconductor package 533 (shown in dashed lines). Although only two power semiconductor packages are shown in FIG. 5F. The number of power semiconductor packages to be separated in a same singulated process may vary.

Those of ordinary skill in the art may recognize that modifications of the embodiments disclosed herein are possible. For example, a height of the elevated section 177 of the second metal clip 170 may vary. Other modifications may occur to those of ordinary skill in this art, and all such modifications are deemed to fall within the purview of the present invention, as defined by the claims.

1. A power semiconductor package comprising:
a lead frame comprising
a first die paddle;
a second die paddle;
a first end paddle; and
a second end paddle;
a low side field-effect transistor (FET) being flipped and attached to the first die paddle, the low side FET comprising a source electrode and a gate electrode on a top surface of the low side FET;
a high side FET attached to the second die paddle, the high side FET comprising a source electrode and a gate electrode on a top surface of the high side FET;
a first metal clip connecting a drain electrode of the low side FET and the source electrode of the high side FET to the first end paddle of the lead frame;
a second metal clip mounted on the second end paddle of the lead frame;
an inductor assembly comprising
a first lead connecting to the first metal clip; and
a second lead connecting to the second metal clip; and
a molding encapsulation enclosing the low side FET, the high side FET, the first metal clip, the second metal clip, the inductor assembly, and a majority portion of the lead frame.

2. The power semiconductor package of claim 1, wherein the first metal clip is electrically and mechanically connected to the drain electrode of the low side FET by a first conductive material;
wherein the first metal clip is electrically and mechanically connected to the source electrode of the high side FET by a second conductive material;
wherein the first metal clip is electrically and mechanically connected to the first end paddle of the lead frame by a third conductive material; and
wherein the second metal clip is electrically and mechanically connected to the second end paddle of the lead frame by a fourth conductive material.

3. The power semiconductor package of claim 2, wherein the first metal clip comprises an elevated section;
wherein the first lead of the inductor assembly is electrically and mechanically connected to the elevated section of the first metal clip by a fifth conductive material;
wherein the second metal clip comprises an elevated section; and
wherein the second lead of the inductor assembly is electrically and mechanically connected to the elevated section of the second metal clip by a sixth conductive material.

4. The power semiconductor package of claim 3, wherein each of the first conductive material, the second conductive material, the third conductive material, and the fourth conductive material comprises a solder paste material.

5. The power semiconductor package of claim 4, wherein each of the fifth conductive material and the sixth conductive material comprises a power metallurgy material.

6. The power semiconductor package of claim 4, wherein each of the fifth conductive material and the sixth conductive material comprises an elastomer material.

7. The power semiconductor package of claim 4, wherein each of the fifth conductive material and the sixth conductive material comprises an epoxy material.

8. The power semiconductor package of claim 4, wherein a bottom surface of the lead frame is exposed from the molding encapsulation.

9. The power semiconductor package of claim 4 further comprising an integrated circuit (IC) mounted on the lead frame, wherein a plurality of bonding wires connect the IC to a plurality of leads of the lead frame.

10. A method for fabricating a power semiconductor package, the method comprising the steps of:
providing a lead frame comprising
a first die paddle;
a second die paddle;
a first end paddle; and
a second end paddle;
attaching a low side field-effect transistor (FET) and a high side FET to the first die paddle, and the second die paddle respectively;
connecting a drain electrode of the low side FET and a source electrode of the high side FET to the first end paddle of the lead frame by a first metal clip;
mounting a second metal clip on the second end paddle of the lead frame;
mounting an inductor assembly so that a first lead of the inductor assembly is connected to the first metal clip and a second lead of the inductor assembly is connected to the second metal clip;
forming a molding encapsulation enclosing the low side FET, the high side FET, the first metal clip, the second metal clip, the inductor assembly, and a majority portion of the lead frame; and
applying a singulation process separating the power semiconductor package from adjacent power semiconductor packages.

11. The method of claim 10, wherein the low side FET is flipped;
wherein the low side FET comprises a source electrode and a gate electrode on a top surface of the low side FET; and
wherein the high side FET comprises the source electrode and a gate electrode on a top surface of the high side FET.

12. The method of claim 11, wherein the step of connecting the drain electrode of the low side FET and the source electrode of the high side FET to the first end paddle of the lead frame by the first metal clip comprises the sub-steps of
applying a first solder paste between the first metal clip and the drain electrode of the low side FET;
applying a second solder paste between the first metal clip and the source electrode of the high side FET;
applying a third solder paste between the first metal clip and the first end paddle of the lead frame; and
applying a reflow process.

13. The method of claim 12, wherein the step of mounting the second metal clip on the second end paddle of the lead frame comprises the sub-steps of
applying a fourth solder paste between the second metal clip and the second end paddle of the lead frame.

14. The method of claim 13, wherein the step of mounting the inductor assembly comprises the sub-steps of
electrically and mechanically connecting the first lead of the inductor assembly to an elevated section of the first metal clip by a first selected conductive material; and
electrically and mechanically connecting the second lead of the inductor assembly to an elevated section of the second metal clip by a second selected conductive material.

15. The method of claim 14, wherein each of the first selected conductive material and the second selected conductive material comprises a power metallurgy material.

16. The method of claim 14, wherein each of the first selected conductive material and the second selected conductive material comprises an elastomer material.

17. The method of claim 14, wherein each of the first selected conductive material and the second selected conductive material comprises an epoxy material.

18. The method of claim 14, wherein a bottom surface of the lead frame is exposed from the molding encapsulation.

19. The method of claim 14, before the step of mounting the inductor assembly, the method further comprising
mounting an integrated circuit (IC) on the lead frame; and
applying a plurality of bonding wires connecting the IC to a plurality of leads of the lead frame.
